(19) United States
(12) Patent Application Publication
(10) Pub. No.: US 2014/0353615 A1
(43) Pub. Date: Dec. 4, 2014

(54) ORGANIC LIGHT EMITTING DISPLAY DEVICE AND METHOD FOR MANUFACTURING THE SAME

(71) Applicant: Samsung Display Co. Ltd., Yongin-City (KR)

(72) Inventor: Hyea Weon SHIN, Yongin-si (KR)

(73) Assignee: Samsung Display Co. Ltd., Yongin-City (KR)

(21) Appl. No.: 14/073,313

(22) Filed: Nov. 6, 2013

(30) Foreign Application Priority Data
May 28, 2013 (KR) 10-2013-0060410

(51) Int. Cl. H01L 51/52; H01L 51/56; H01L 27/32

(52) U.S. Cl. CPC H01L 51/5203; H01L 27/32; H01L 51/56
USPC 257/40; 438/34

(57) ABSTRACT

Provided are an organic light emitting display device and a method for manufacturing the same. The organic light emitting display device includes a substrate, first electrode positioned on the substrate, a pixel defining film positioned on the substrate and at least partially exposing the first electrode, an organic layer positioned on the first electrode and having a central portion and an edge portion, and a cover film at least partially overlapping the edge portion of the organic layer.

### CROSS-REFERENCE TO RELATED APPLICATION

This application claims priority from Korean Patent Application No. 10-2013-0060410 filed on May 28, 2013 in the Korean Intellectual Property Office, the disclosure of which application is incorporated herein by reference in its entirety.

### BACKGROUND

1. Field of the Invention

The present invention relate to an organic light emitting display device and a method for manufacturing the same. More particularly, the present invention relate to an organic light emitting display device including an electrode and an organic layer formed on the electrode, and a method for manufacturing the organic light emitting display device.

2. Description of Related Technology

A display that provides users with a variety of informational content on a screen is a core technology in the information-oriented communication age and is trending toward increased slimness, lightness in weight, portability and high performance. Accordingly, growing attention has been paid to thin (e.g., flat) panel displays including organic light emitting display devices (OLEDD's), which can overcome drawbacks of the conventional cathode ray tube (CRT), which is heavy-weighted and large-sized,

Here, the organic light emitting display device is a self-emissive device using a thin organic light-emitting layer disposed between electrodes. It is advantageous because it is capable of implementing greater slimness. Organic light emitting display devices are classified into small molecule organic light emitting display devices and polymer organic light emitting display devices according to the materials used for forming the organic light-emitting layer which is used for generating light. The organic light-emitting layer of the small molecule organic light emitting display device is generally formed as a relatively thin film by vacuum deposition. On the other hand, the organic light-emitting layer of the polymer molecule organic light emitting display device is generally formed also as a relatively thin film by a solution coating method, such as spin coating or ink jet printing. The thinness of the organic light-emitting layer might allow for short circuits to develop where the organic light-emitting layer is patterned into segments having respective segment boundaries or edges.

Additionally, the organic light-emitting layer of the polymer molecule kind may have non-uniform thicknesses due to a problem arising in the organic light-emitting layer forming process, which may cause not only electric shorts between electrodes disposed on opposite sides of thin segments of the organic light-emitting layer but also non-uniform light emission due to irregular boundaries at the edges of the thin segments. Accordingly, mass production of consistent product with minimized number of shorts and consistent emission of light for every pixel can be a problem. A variety of technical attempts for solving the problem are being tried.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding invention dates of subject matter disclosed herein.

### SUMMARY OF THE INVENTION

Disclosed here are organic light emitting display devices wherein a relatively thin, organic light emitting layer separates one or more upper electrodes (second electrodes) from opposed lower electrodes (first electrodes) and thus there is the danger of short circuits developing at edge regions of light emitting segments of the organic light emitting layer. This danger is reduced or eliminated by interposing along the edge regions of the light emitting segments, an insulative cover film that extends to immediately adjacent top portions of a pixel areas defining film such that material of the upper electrode(s) cannot fall into crevices which might form when the upper electrode material is deposited on a substrate already having formed thereon the lower electrodes, the pixel areas defining film and the light emitting segments.

The present invention provides an organic light emitting display device, which can prevent an electric short generated between an electrode and an organic layer. The present invention also provides a method for manufacturing an organic light emitting display device, which can prevent an electric short generated between an electrode and an organic layer.

The above and other objects of the present invention will be described in or be apparent from the following description of the preferred embodiments.

According to an aspect of the present invention, there is provided an organic light emitting display device including a substrate, a first electrode positioned on the substrate, a pixel defining film positioned on the substrate and at least partially exposing the first electrode, an organic layer positioned on the first electrode and having a central portion and an edge portion, and a cover film at least partially overlapping the edge portion of the organic layer.

According to another aspect of the present invention, there is provided an organic light emitting display device, including a substrate, a first electrode positioned on the substrate, a plurality of pixels exposing at least a portion of the first electrode, an organic layer positioned on each of the plurality of pixels, and a cover film disposed along edges of the pixels.

According to still another aspect of the present invention, there is provided a method for manufacturing an organic light emitting display device, the method including preparing a substrate, the substrate including a first electrode positioned on the substrate, and a pixel defining film positioned on the substrate and at least partially exposing the first electrode, patterning an organic layer having a central portion and an edge portion on the first electrode, and disposing a cover film at least partially overlapping the edge portion of the organic layer.

Embodiments of the present invention provide at least the following effects.

That is to say, the organic light-emitting display device can prevent an electric short from occurring between a first electrode and a second electrode.

In addition, a cover film is disposed between an organic layer and an electrode, thereby suppressing non-uniform emission from occurring at an edge portion of the organic layer.

### BRIEF DESCRIPTION OF THE DRAWINGS

The above and other features and advantages of the present disclosure of invention will become more apparent by describing in detail preferred embodiments with reference to the attached drawings in which:

FIG. 1 is a plan view schematically illustrating an organic light emitting display device according to an embodiment of the present disclosure;

FIG. 2 is a cross-sectional view taken along line I-I′ of FIG. 1;

FIG. 3 is an enlarged cross-sectional view illustrating an organic layer shown in FIG. 2 and its surrounding area;

FIG. 4 is a cross-sectional view illustrating an organic light emitting display device according to another embodiment;

FIG. 5 is an enlarged cross-sectional view illustrating an organic layer shown in FIG. 4 and its surrounding area;

FIG. 6 is an enlarged cross-sectional view illustrating an organic layer according to another embodiment;

FIG. 7 is a plan view illustrating an organic light emitting display device according to another embodiment;

FIG. 8 is a cross-sectional view taken along the line II-II′ of FIG. 7;

FIG. 9 is a cross-sectional view illustrating an organic light emitting display device according to another embodiment; and

FIGS. 10 to 14 are cross-sectional views illustrating a method for manufacturing the organic light emitting display device according to an embodiment of the present disclosure.

### DETAILED DESCRIPTION OF THE INVENTION

The aspects and features of the present disclosure and methods for achieving the aspects and features will become more apparent by referring to the embodiments to be described in detail with reference to the accompanying drawings. However, the present teaching is not limited to the embodiments disclosed hereinafter, but can be implemented in diverse forms. The matters defined in the description, such as the detailed construction and elements, are nothing but specific details provided to assist those of ordinary skill in the art in a comprehensive understanding of the present disclosure of invention, and the present invention is only defined within the scope of the appended claims.

The term “on” that is used to designate that an element is on another element or located on a different layer or a layer includes both a case where an element is located directly on another element or a layer and a case where an element is located on another element via another layer or still another element. In the description, the same drawing reference numerals are used for the same elements across various figures.

Although the terms “first, second, and so forth” are used to describe diverse constituent elements, such constituent elements are not limited by the terms. The terms are used only to discriminate a constituent element from other constituent elements. Accordingly, in the following description, a first constituent element may he a second constituent element.

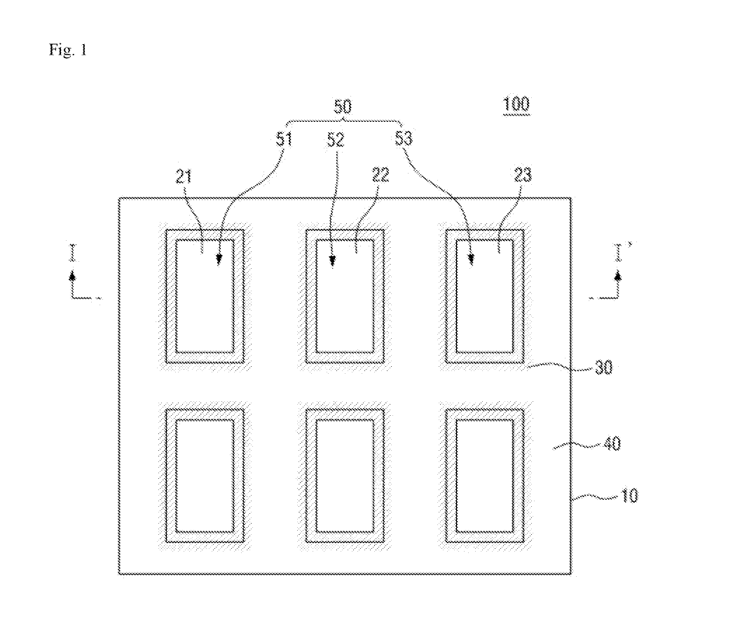

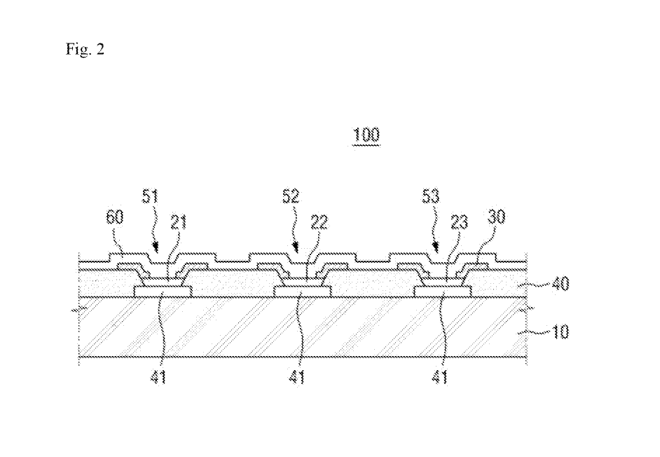

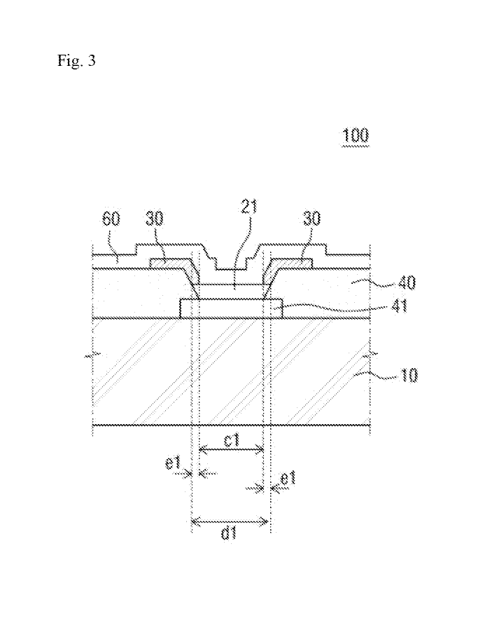

The present teachings will now be provided more fully hereinafter with reference to the accompanying drawings, in which exemplary embodiments are shown. FIG. 1 is a plan view schematically illustrating an organic light emitting display device according to an embodiment of the present invention, FIG. 2 is a cross-sectional view taken along the line I-I′ of FIG. 1, and FIG. 3 is an enlarged cross-sectional view illustrating an organic layer shown in FIG. 2 and its surrounding area.

Referring to FIGS. 1 and 2, the organic light emitting display device 100 according to the embodiment of the present invention includes a substrate 10, a first electrode 41 positioned on the substrate 10, a pixel defining film 40 positioned on the substrate 10 and exposing at least a portion of the first electrode 41, an organic layer 50 positioned on the first electrode 41, and a cover film 30 positioned on the pixel defining film 40 and at least partially overlapping the pixel defining film 40

The substrate 10 may be a unit display substrate and may be a mother board before it is cut and partitioned into a plurality of unit display substrates. The substrate 10 may be a sheet of a substrate, but may include a plurality of substrates stacked one on another.

The substrate 10 may include an insulating substrate. The insulating substrate may be made of transparent glass containing transparent SO₂ as a main component.

In some embodiments, the substrate 10 may be made of an opaque material or a plastic material. Further, the substrate 10 may be a flexible substrate that is bendable, foldable or rollable.

Although not shown, the substrate 10 may further include additional structures formed on the insulating substrate. Examples of the additional structures may include wirings, electrodes, insulating layers, and so on. If the organic light emitting display device 100 of FIGS. 1-3 is an active type organic light emitting display device, the substrate 10 may include a plurality of thin film transistors (not shown) formed on the substrate 10. The thin film transistors may include a gate electrode (not shown), a source electrode (not shown) and a drain electrode (not shown), and a semiconductor layer (not shown) as a channel region. The semiconductor layer may be made of amorphous silicon, poly crystalline silicon, or single crystalline silicon. In another embodiment, the semiconductor layer may include an oxide semiconductor. Drain electrodes of at least some of the plurality of thin film transistors may be electrically connected to the first electrode 41.

The first electrode 41 may be positioned on the substrate 10. The first electrode 41 may be spaced apart from the substrate 10. The first electrode 41 may be an anode electrode or a cathode electrode. If the first electrode 41 is an anode electrode, the second electrode 53 may be a cathode electrode. Based on the assumption, the following embodiments will be described. However, the present disclosure is not limited thereto and the first electrode may be a cathode electrode and the second electrode may be an anode electrode.

If the first electrode 41 is used as the anode electrode, it may be made of a conductive material having a high work function. If the organic light emitting display device 100 is a bottom emission type display device, the first electrode 41 may be made of ITO, IZO, ZnO, or In₂O₃, or a stack thereof. If the organic light emitting display device 41 is a front emission type display device, the first electrode 41 may further include a reflective film made of Ag, Mg, Al, Pt, Pd, Au, Ni, Nd, Ir, Cr, Li, or Ca.

The first electrode 41 may be modified to various structures, including a structure having two or more layers of two or more different materials.

The pixel defining film 40 may be formed on the first electrode 41. The pixel defining film 40 may expose at least a portion of the first electrode 41. That is to say, in an exemplary embodiment, the pixel defining film 40 may partially expose the first electrode 41 or may entirely expose the first electrode 41. When the pixel defining film 40 entirely exposes the first electrode 41, the first electrode 41 may be spaced apart from the pixel defining film 40 adjacent thereto. The pixel defining film 40 may include at least one selected from the group consisting of benzocyclobutene (BCB), polyimide (PI), poly amide (PA), acryl resin and phenol resin, or an inorganic material, such as silicon nitride. The pixel defining film 40 may also include a photosensitizer containing a black pigment. In this case, the pixel defining film 40 may serve as a light shielding member.

The organic layers 21, 22 and 23 may be positioned on the first electrode 41. The organic layers 21, 22 and 23 may include organic material layers included in the organic light emitting display device 100, that is, an organic light emitting layer (EML), a hole injection layer (HIL), a hole transport layer (HTL), an electron injection layer (EIL, an electron transport layer (ETL), and so on. The organic layers 21, 22 and 23 may have a single layered structure including one layer selected from the organic material layers or a multiple layered structure including two or more layers selected from the organic material layers. The organic layers 21, 22 and 23 may emit respective but different colors of light such as Red, Green and Blue.

Each of the organic layers 21, 22 and 23 may include a central portion and an edge portion. The central portion and the edge portion of the organic layer will be described in detail with reference to FIG. 3.

Referring to FIG. 3, the organic layers 21, 22 and 23 of the organic light emitting display device 100 may be flat.

In each of the organic layers 21, 22 and 23 including a central portion and an edge portion, the edge portion may be a region overlapping the pixel defining film adjacent thereto (a region e1 in FIG. 3) and the central portion may be a region excluding the edge portion from the organic layer (a region c1 in FIG. 3). FIG. 3 illustrates that the organic layers 21, 22 and 23 are flat, but the present disclosure does not limit the shapes of the organic layers 21, 22 and 23 thereto. In an exemplary embodiment, the edge portion and the central portion may have different thicknesses. In addition, the thickness of the edge portion and/or the thickness of the central portion may not be uniform.

Each of the organic layers 21, 22 and 23 may include a light emitting area. In the light emitting area of each of the organic layers 21, 22 and 23, holes and electrons generated by the first electrode 41 and the second electrode 60 may be combined with each other. That is to say, excitons may generated when the holes and electrons are combined with each other in the light emitting area of each of the organic layers 21, 22 and 23, and when energy levels of the generated excitons are changed from an excited state and a ground state, light corresponding to the changed energy level may be emitted.

The light emitting area may be substantially equal to or smaller than an overlapping area between the first electrode 41 and each of the organic layers 21, 22 and 23. That is to say, a width of the light emitting area may be equal to or smaller than a width (d1 of FIG. 3) of the overlapping area between first electrode 41 and each of the organic layers 21, 22 and 23. In an exemplary embodiment, the width of the light emitting area may be substantially equal to or smaller than the width of the organic layer central portion, i.e., c1.

The organic layers 21, 22 and 23 may include a plurality of layers. The plurality of organic layers 21, 22 and 23 may include a first organic layer 21, a second organic layer 22, and a third organic layer 23. The plurality of organic layers 21, 22 and 23 may include different materials, but aspects of the present disclosure are not limited thereto. At least two of the first organic layer 21, the second organic layer 22 and the third organic layer 23 may include the same material. In addition, the first organic layer 21, the second organic layer 22, and the third organic layer 23 may have the same stacked structure, but aspects of the present invention are not limited thereto. That is to say, at least one of the first organic layer 21, the second organic layer 22, and the third organic layer 23 may have a different stacked structure from the other layer(s).

In an exemplary embodiment, the first organic layer 21, the second organic layer 22, and the third organic layer 23 may emit different colors, but aspects of the present disclosure are not limited thereto. That is to say, at least two of the first organic layer 21, the second organic layer 22, and the third organic layer 23 may emit the same color. In the exemplary embodiment shown in FIGS. 1 and 2, the first organic layer 21 may emit a red color, the second organic layer 22 may emit a green color, and the third organic layer 23 may emit a blue color.

The may be disposed on the edge portion of each of the organic layers 21, 22 and 23. That is to say, the cover film 30 may be disposed to at least partially overlap the edge portion. That is to say, the cover film 30 may partially or entirely the edge portion, but aspects of the present invention are not limited thereto. In another exemplary embodiment, in a state in which the cover film 30 covers the edge portion, it may extend by a predetermined distance toward the central portion or the pixel defining film 40 adjacent thereto.

The cover film 30 may be made of a non-conductive material. The cover film 30 may include an inorganic material, that is, at least one of silicon oxide and silicon nitride, but aspects of the present invention are not limited thereto. That is to say, the cover film 30 may include an organic material or a metal material.

Examples of the organic material included in the cover film 30 may include polyacrylate and polyimide. However, the present invention does not limit the material of the cover film 30 to those listed herein, but any material can be used as the cover film 30 as long as it has a resistance value of 10 Ω/cm² or less.

The cover film 30 may have a thickness in a range of 10 Å (angstrom) to 5 μm, which is, however, provided only for illustration. The present disclosure does not limit the thickness of the cover film 30 to that listed herein.

The cover film 30 may be formed by, for example, laser induced thermal imaging (LITI), but not limited thereto. The cover film 30 may be formed by various methods. For example, the cover film 30 may be formed by printing or deposition. The method for forming the cover film 30 will later be described in detail.

The second electrode 60 may be formed on the organic layers 21, 22 and 23. When the second electrode 60 is used as a cathode electrode, it may be made of a conductive material having a low work function. In an exemplary embodiment, the second electrode 60 may be made of Ag, Mg, Al, Pt, Pd, Au, Ni, Nd, Ir, Cr, Li, or Ca.

The second electrode 60 may be continuous on the substrate 10. That is to say, the second electrode 60 may completely cover underlying structures of the second electrode 60, for example, the organic layers 21, 22 and 23 and the pixel defining film 40. For example, the second electrode 60 positioned on the organic layers 21, 22 and 23 and the second electrode 60 positioned on the pixel defining film 40 may be connected to each other. In another exemplary embodiment, the second electrode 60 may be discontinuous on a partial region of the substrate 10. For example, the second electrode 60 positioned on the organic layers 21, 22 and 23 and the second electrode 60 positioned on the pixel defining film 40 may be spaced apart from each other.

The plan view of the organic light emitting display device according to the embodiment of the present disclosure will be described with reference to FIG. 1.

Referring to FIG. 1, the organic light emitting display device 100 according to the embodiment of the present disclosure may include a plurality of pixels disposed on the substrate 10.

The plurality of pixels 51, 52 and 53 may be positioned on regions exposed by the pixel defining film 40. That is to say, the plurality of pixels 51, 52 and 53 may be positioned on openings of the pixel defining film 40. That is to say, the plurality of pixels 51, 52 and 53 may be separated from each other by the pixel defining film 40. Each of the plurality of pixels 51, 52 and 53 may include the first electrode 41, the second electrode 60 positioned on the first electrode 41, and the organic layers 21, 22 and 23 positioned between the respective first electrode 41 and the corresponding portion of the second electrode 60.

The plurality of pixels may include the first pixel 51, the second pixel 52, and the third pixel 53.

FIG. 1 illustrates the plurality of pixels 51, 52 and 53 are rectangular, but the present disclosure does not limit the shape of each pixel to that illustrated herein. That is to say, the pixel may be circular, oval or polygonal. In addition, the first pixel 51, the second pixel 52 and the third pixel 53 may have the same shape, but aspects of the present disclosure are not limited thereto. The plurality of pixels 51, 52 and 53 may have different shapes.

The first pixel 51, the second pixel 52, and the third pixel 53 may emit different colors, but aspects of the present disclosure are not limited thereto. At least two of the first pixel 51, the second pixel 52, and the third pixel 53 may emit the same color. In an exemplary embodiment, the first pixel 51 may emit a red color, the second pixel 52 may emit a green color, and the third pixel 53 may emit a blue color.

The plurality of pixels 51, 52 and 53, that is, the first pixel 51, the second pixel 52, and the third pixel 53, may be disposed in a matrix configuration. An nth column of each of the plurality of pixels 51, 52 and 53 may include a plurality of first pixels 51, an (n+1)th column adjacent to the nth column includes a plurality of second pixels 52, and an (n+2)th column adjacent to the (n+1)th column may include a plurality of third pixels 53. In an exemplary embodiment, the nth column, the (n+1)th column, and the (n+2)th column may be parallel to each other, but aspects of the present disclosure are not limited thereto. The plurality of pixels 51, 52 and 53 may be arranged such that the nth column, the (n+1)th column, and the (n+2)th column are repeatedly arranged in that order in a row direction. Here, n is a natural number, that is, an integer greater than 0, and each of the plurality of pixels 51, 52 and 53 may be formed at an intersection of a row and a column.

The first pixel 51 may be adjacent to the second pixel 52 and the third pixel 53 in a row direction, and may be adjacent to another first pixel 51 in a column direction. The second pixel 52 may be adjacent to the first pixel 51 and the third pixel 53 in a row direction, and may be adjacent to another second pixel 52 in a column direction. The third pixel 53 may be adjacent to the first pixel 51 and the second pixel 52 in a row direction, and may be adjacent to another third pixel 53 in a column direction.

The plurality of pixels 51, 52 and 53 may be positioned on regions exposed by the pixel defining film 40. That is to say, the plurality of pixels 51, 52 and 53 may be positioned on openings of the pixel defining film 40. That is to say, the plurality of pixels 51, 52 and 53 may be separated from each other by the pixel defining film 40. Each of the plurality of pixels 51, 52 and 53 may include the first electrode 41, the second electrode 60 positioned on the first electrode 41, and the organic layers 21, 22 and 23 positioned between the first electrode 41 and the second electrode 60.

The plurality of pixels 51, 52 and 53 may include a first pixel 51, a second pixel 52, and a third pixel 53.

Referring to FIG. 1, the plurality of pixels 51, 52 and 53, that is, the first pixel 51, the second pixel 52, and the third pixel 53 may be rectangular, but the present disclosure of invention does not limit the shape of each pixel to that illustrated herein. That is to say, the pixel may be circular, oval or polygonal. In addition, at least one of the first pixel 51, the second pixel 52 and the third pixel 53 may have a different shape from the other pixels.

The cover film 30 may be disposed along the edge of each pixel. In more detail, as described above, the cover film 30 may cover edge portions of the organic layers 21, 22 and 23. In an exemplary embodiment, the respective edge portions of the organic layers 21, 22 and 23 may be disposed along the edge portions of the pixels 51, 52 and 53, and the cover film 30 may cover the edge portions of the organic layers 21, 22 and 23 disposed along the edges of the pixels 51, 52 and 53. In other words, the cover film 30 may be disposed to overlap the edge portions of the organic layers 21, 22 and 23 disposed along the edges of the pixels 51, 52 and 53.

In addition, as described above, the cover film 30 may extend toward the pixel defining film 40 adjacent thereto and may cover at least a portion of the pixel defining film 40 disposed along the edges of the pixels 51, 52 and 53. That is to say, the cover film 30 may be disposed to overlap at least a portion of the pixel defining film 40 adjacent to the edge portion of the organic layers 21, 22 and 23.

When the cover film 30 covers the edge portions of the organic layers 21, 22 and 23, an electric short generated between the first electrode 41 and the second electrode 60 may be suppressed.

Hereinafter, other embodiments of the present disclosure will be described. In the following embodiments, the same functional components are denoted by the same reference numerals of the previous embodiment and repeated explanations will not be given or will be briefly made.

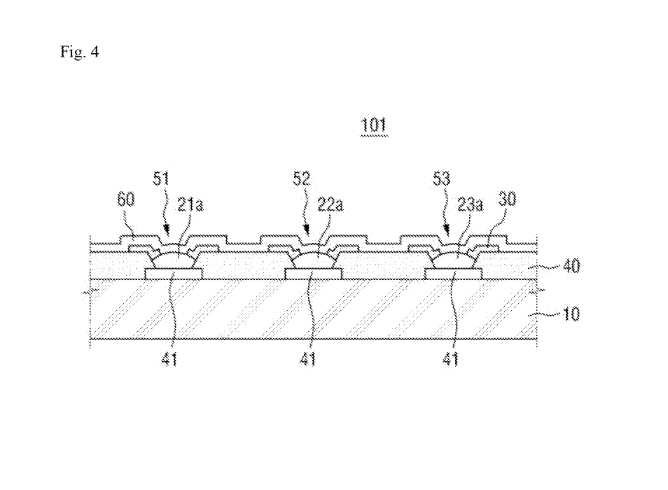

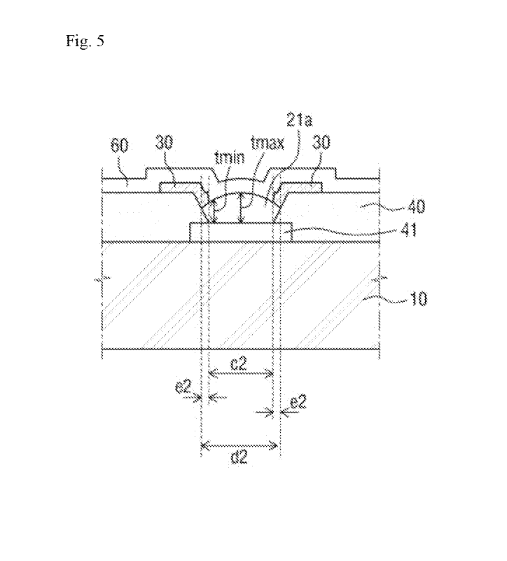

FIG. 4 is a cross-sectional view illustrating an organic light emitting display device according to another embodiment of the present disclosure and FIG. 5 is an enlarged cross-sectional view illustrating an organic layer shown in FIG. 4 and its surrounding area.

Referring to FIGS. 4 and 5, the organic light emitting display device 101 according to the present embodiment is different from the organic light emitting display device according to the previous embodiment shown in FIG. 2 in that organic layers are shaped to have non-flat top surfaces, for example those with an upwardly convex parabola shape.

Each of the organic layers 21a, 22a and 23a shaped of an upwardly convex parabola may include a central portion and edge portions disposed with the central portion disposed therebetween. The edge portion may include a region overlapping the pixel defining film 40 adjacent thereto (a region e2 in FIG. 5).

That is to say, in an exemplary embodiment, a region of the organic layer 21a overlapping the pixel defining film 40 adjacent thereto may be the edge portion, and a region of the organic layer 21a, excluding the edge portion from the organic layer 21a may be the central portion (a region c2 in FIG. 5).

A thickness of the central portion may be larger than that of the edge portion. Throughout the specification of the present disclosure, the thickness of the central portion or the edge portion may mean a shortest distance ranging from the substrate 10 to the top surface of each of the organic layers 21a, 22a and 23a. If the organic layers 21a, 22a and 23a are convexly shaped, heights of the central portion and the edge portion may not be uniform. In this case, a minimum thickness (tmin) of the central portion may be equal to or greater than a maximum thickness (tmax) of the edge portion.

The cover film 30 may be disposed on the edge portions of the organic layers 21a, 22a and 23a. That is to say, the cover film 30 may be disposed to at least partially overlap the edge portions. That is to say, the cover film 30 may partially or entirely the edge portion, but aspects of the present disclosure are not limited thereto. In another exemplary embodiment, the cover film 30 may extend toward the central portion in a state in which the edge portion is covered or the pixel defining film 40 adjacent thereto.

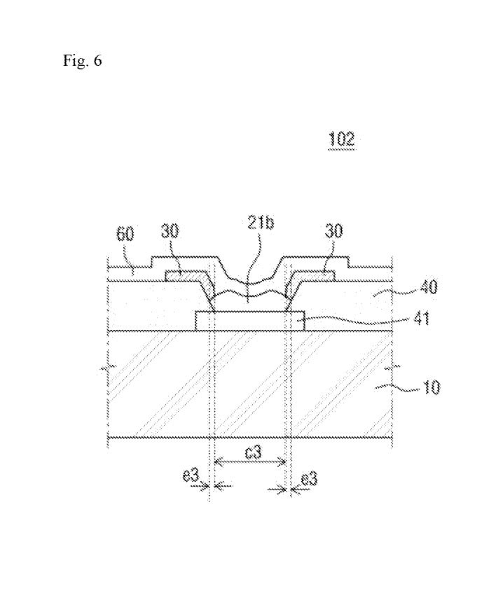

FIG. 6 is an enlarged cross-sectional view illustrating an organic layer according to another embodiment of the present disclosure and its surrounding area.

Referring to FIG. 6, the organic light emitting display device 102 according to the present embodiment is different from the organic light emitting display device 100 according to the previous embodiment shown in FIG. 2 in that thicknesses of the organic layers are not uniform.

As described above, the thickness of the organic layer 21b may not be uniform. FIG. 6 illustrates that the organic layer 21b has a recessed central region at its central portion (a region c3 in FIG. 6) and protruding regions at its opposite side portions while its edge portion (a region e3 in FIG. 6) is recessed, which is, however, provided only for illustration. The present disclosure does not limit the shape of the organic layer 21b to that illustrated herein.

As described above, the edge portion may include a region of the organic layer 21b overlapping the pixel defining film 40 adjacent thereto, and the central portion may be a region excluding the edge portion from the organic layer 21b.

The cover film 30 may be disposed on the edge portion of the organic layer 21b. That is to say, the cover film 30 may be disposed to at least partially overlap the edge portion. That is to say, the cover film 30 may partially or entirely the edge portion, but aspects of the present disclosure are not limited thereto. In another exemplary embodiment, in a state in which the cover film 30 covers the edge portion, it may extend by a predetermined distance toward the central portion or the pixel defining film 40 adjacent thereto.

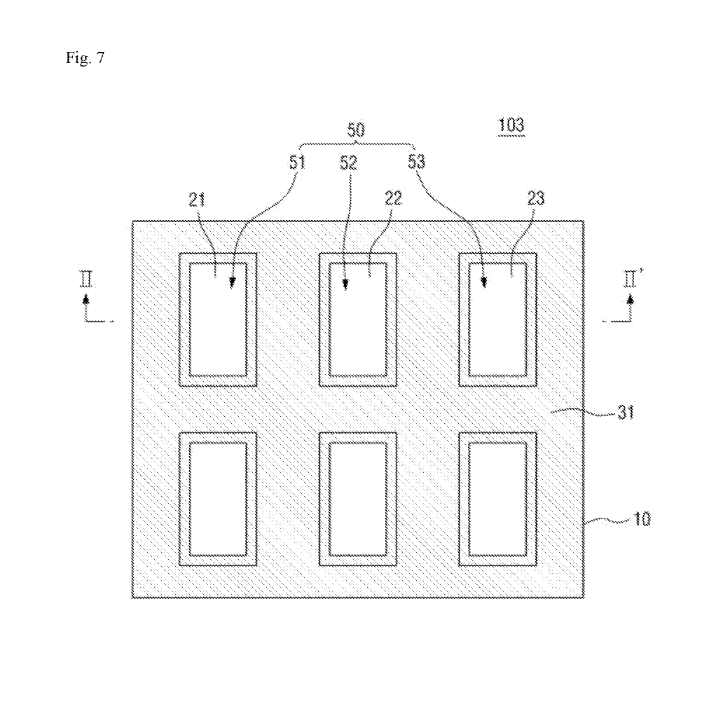

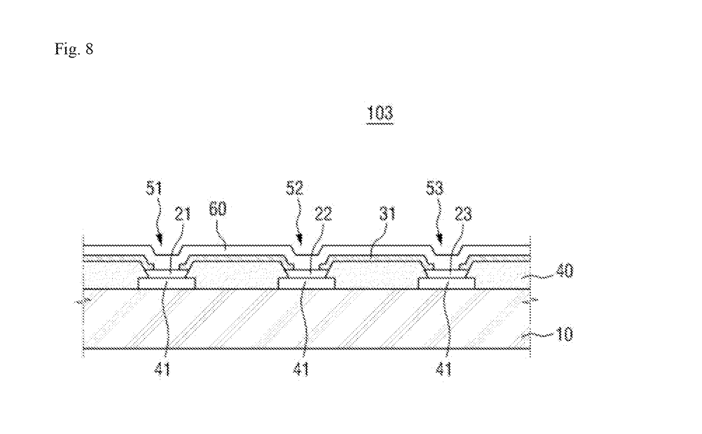

FIG. 7 is a plan view illustrating an organic light emitting display device according to another embodiment of the present disclosure and FIG. 8 is a cross-sectional view taken along the line II-II′ of FIG. 7.

Referring to FIGS. 7 and 8, the organic light emitting display device 103 according to the present embodiment is different from the organic light emitting display device 100 according to the previous embodiment shown in FIG. 1 in that a cover film entirely covers organic layers 21, 22 and 23, excluding central portions of the organic layers 21, 22 and 23.

As described above, the cover film 31 covering the edge portions of the organic layers 21, 22 and 23 may extend toward a pixel defining film 40 adjacent thereto. If the cover film 31 continuously extends, it may be connected to the cover film 31 covering the edge portions of the organic layers 21, 22 and 23 disposed at adjacent pixels. That is to say, as shown in FIG. 5, the covering one edge portion of the first pixel 51 may extend to reach one side of the substrate 10. For the sake of convenient explanation, in FIG. 5, the edge portion disposed in the left side of each of the organic layers 21, 22 and 23 is denoted by one edge portion and the edge portion disposed in the right side of each of the organic layers 21, 22 and 23 is denoted by one edge portion, organic layers 21, 22 and 23 is denoted by the other edge portion. In addition, the cover film 31 covering the other edge portion of the first pixel 51 may be connected to the cover film 31 covering one edge portion of the second pixel 52, thereby entirely covering the pixel defining film 40 disposed between the first pixel 51 and the second pixel 52. Likewise, the cover film 31 covering the other edge portion of the second pixel 52 may be connected to the cover film 31 covering one edge portion of the third pixel 53, thereby entirely covering the pixel defining film 40 disposed between the second pixel 52 and the third pixel 53.

In other words, the cover film 31 may cover the entire region of the substrate 10 having the plurality of pixels 51, 52 and 53 disposed thereon, excluding the central portions of the organic layers 21, 22 and 23 positioned on the plurality of pixels 51, 52 and 53.

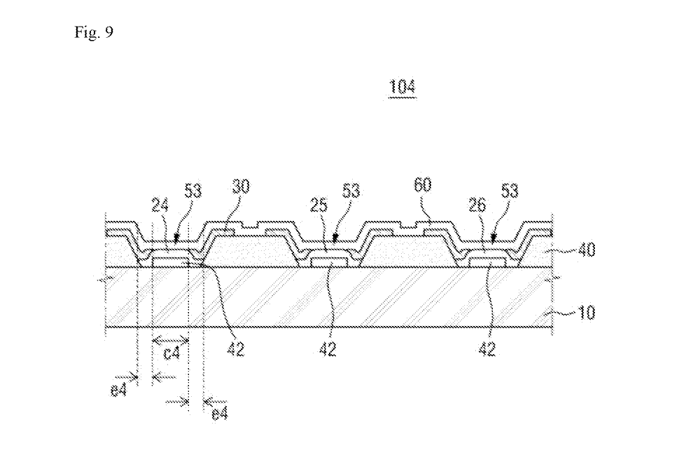

FIG. 9 is a cross-sectional view illustrating an organic light emitting display device according to another embodiment of the present disclosure.

Referring to FIG. 9, the organic light emitting display device 104 according to the present embodiment is different from the organic light emitting display device 100 according to the previous embodiment shown in FIG. 1 in that a pixel defining film 40 entirely exposes a first electrode 42.

In an exemplary embodiment, the pixel defining film 40 may entirely expose the first electrode 42. In this case, the first electrode 42 and the pixel defining film 40 may be spaced a predetermined distance apart from each other.

As described above, organic layers 24, 25 and 26 may be disposed on the first electrode 42. In an exemplary embodiment, the organic layers 24, 25 and 26 may entirely cover the first electrode 42. In addition, the organic layers 24, 25 and 26 entirely covering the first electrode 42 may come into contact with the pixel defining film 40 adjacent to the first electrode 42.

As described above, each of the organic layers 24, 25 and 26 may include an edge portion and a central portion. In the organic light emitting display device 104 according to the present embodiment, a central portion (a region c4 in FIG. 9) may be a region of each of the organic layers 24, 25 and 26, overlapping the first electrode 42 adjacent thereto, may be the edge portion, and an edge portion (a region e4 in FIG. 9) may be a region excluding the edge portion from each of the organic layers 24, 25 and 26.

The cover film 30 may partially or entirely the edge portion of each of the organic layers 24, 25 and 26. In other words, the cover film 30 may be disposed to partially or entirely overlap the edge portions of the organic layers 24, 25 and 26, but aspects of the present disclosure are not limited thereto. The cover film 30 may extend by a predetermined distance toward the central portion of the pixel defining film 40 adjacent thereto in a state in which it covers the edge portion.

As described above, each of the organic layers 24, 25 and 26 may include a light emitting area. In an exemplary embodiment, the light emitting area of each of the organic layers 24, 25 and 26 may be substantially equal to or smaller than an area of each of the organic layers 24, 25 and 26 overlapping the first electrode 42. In other words, from the cross-sectional view of FIG. 9, a width of the light emitting area may be equal to or smaller than a width of each of the organic layers 24, 25 and 26 overlapping the first electrode 42.

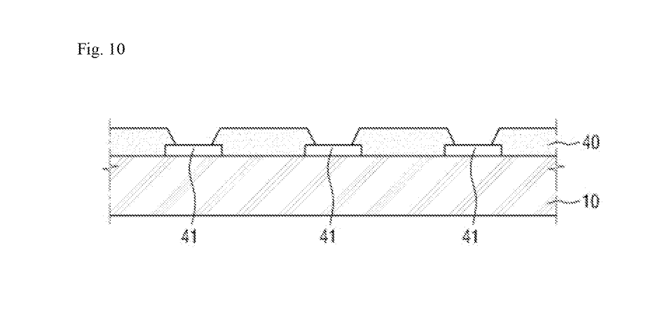

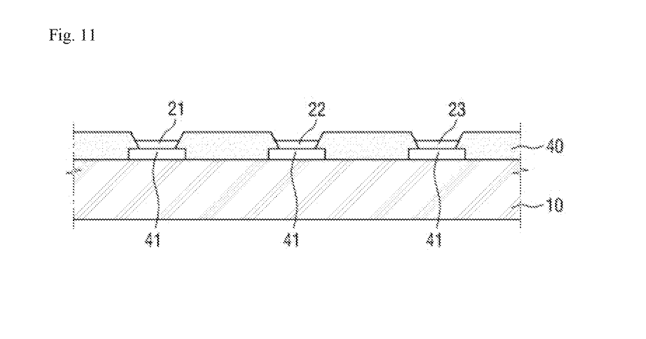

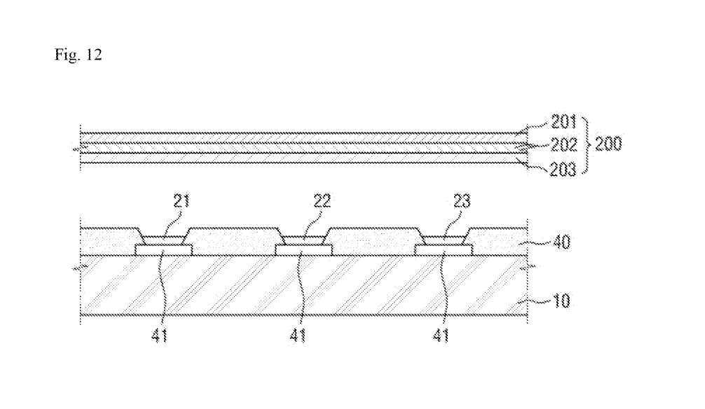

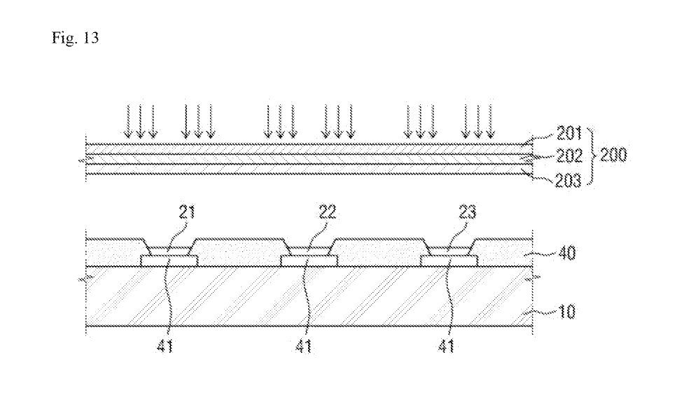

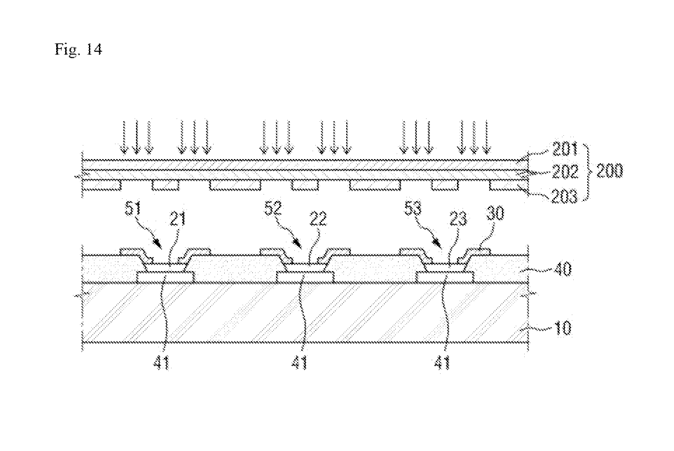

Hereinafter, a method for manufacturing the organic light emitting display device according to an embodiment of the present disclosure will be described with reference to FIGS. 10 to 14. FIGS. 10 to 14 are cross-sectional views illustrating a method for manufacturing the organic light emitting display device according to an embodiment of the present disclosure. Specifically, FIG. 10 is a cross-sectional view illustrating a step of preparing a substrate 10 in the method for manufacturing the organic light emitting display device according to an embodiment of the present disclosure, the substrate 10 including a first electrode 41 positioned thereon and a pixel defining film 40 positioned on the first electrode 41 and at least partially exposing the first electrode 41. FIG. 11 is a cross-sectional view illustrating a step of patterning organic layers 21, 22 and 23 each having a central portion and an edge portion on the first electrode 41 in the method for manufacturing the organic light emitting display device according to an embodiment of the present disclosure. FIG. 12 is a cross-sectional view illustrating a step of positioning a doner substrate 200 on the substrate 10 in the method for manufacturing the organic light emitting display device according to an embodiment of the present disclosure. FIG. 13 is a cross-sectional view illustrating a step of irradiating laser on the doner substrate 200 in the method for manufacturing the organic light emitting display device according to an embodiment of the present disclosure. FIG. 14 is a cross-sectional view illustrating a step of disposing a cover film 30 on the substrate 10 in the method for manufacturing the organic light emitting display device according to an embodiment of the present disclosure.

The method for manufacturing the organic light emitting display device according to an embodiment of the present disclosure includes preparing the substrate 10, including a first electrode 41 positioned thereon and a pixel defining film 40 positioned on the first electrode 41 and at least partially exposing the first electrode 41, patterning organic layers 21, 22 and 23 each having a central portion and an edge portion on the first electrode 41, and disposing a cover film 30 at least partially overlapping the edge portion of each of the organic layers 21, 22 and 23 on the substrate 10.

Referring to FIG. 10, the substrate 10 is prepared, the substrate 10 including the first electrode 41 positioned thereon, and the pixel defining film 40 positioned on the first electrode 41 and at least partially exposing the first electrode 41. The substrate 10, the first electrode 41 and the pixel defining film 40 may be substantially the same as those of each of the above-described organic light emitting display device according to some embodiments of the present disclosure, and detailed descriptions thereof will be omitted.

Referring to FIG. 11, the organic layers 21, 22 and 23 each having a central portion and an edge portion are patterned on the first electrode 41. The method of patterning the organic layers 21, 22 and 23 on the first electrode 41 is not limited to that illustrated herein. The organic layers 21, 22 and 23 may be patterned on the first electrode 41 in various manners.

The organic layers 21, 22 and 23 each having a central portion and an edge portion may be substantially the same as those of each of the above-described organic light emitting display device according to some embodiments of the present disclosure, and detailed descriptions thereof will be omitted.

Next, the cover film 30 at least partially overlapping the edge portion of each of the organic layers 21, 22 and 23 may be disposed. The cover film 30 may be formed by laser induced thermal imaging (LITI), which will now be described in detail with reference to FIGS. 12 to 14.

The disposing of the cover film 30 at least partially overlapping the edge portion of each of the organic layers 21, 22 and 23 may include positioning the doner substrate 200 on the substrate 10 to face the first electrode 41 of the substrate 10, the doner substrate 200 including a base layer 201, a light-to-heat conversion layer 202 positioned on the base layer 201, and a transfer layer 203 positioned on the light-to-heat conversion layer 202, and transferring the transfer layer 203 on the pixel defining film 40 of the substrate 10 by irradiating laser on the doner substrate 200. In the method for manufacturing the organic light emitting display device according to an embodiment of the present disclosure, the cover film 30 may be formed by laser induced thermal imaging (LITI).

Referring to FIG. 12, after the organic layers 21, 22 and 23 are formed on the substrate 10, the doner substrate 200 may be positioned on the substrate 10. FIG. 9 illustrates that the doner substrate 200 and the substrate 10 are spaced apart from each other, but aspects of the present disclosure are not limited thereto. Alternatively, the doner substrate 200 and the substrate 10 may come into contact with each other to then be laminated.

The doner substrate 200 may include the base layer 201, the light-to-heat conversion layer 202 and the transfer layer 203. However, in an alternate embodiments, the conversion layer 202 and the transfer layer 203 may be joined as single homogenous layer.

The base layer 201 may be made of a transparent polymer, and usable examples of the transparent polymer may include polyester such as polyethylene terephthalate, polyacryl, polyepoxy, polyethylene, or polystyrene. Specifically, a polyethylene terephthalate film may be generally used as the transparent polymer. In addition, glass may be used as the base layer 201. The base layer 201 should have an optical property as a supporting film and mechanical stability. The base layer 201 may have a thickness in a range of 10 to 500 μm.

The base layer 201 may be shaped to correspond to the substrate 10. In an exemplary embodiment, a shape and an area of one surface of the base layer 201 may be the same as those of one surface of the substrate 10. In another exemplary embodiment, the base layer 201 may be large enough to cover the substrate 10.

The light-to-heat conversion layer 202 may be positioned on the base layer 201. The light-to-heat conversion layer 202 is a layer that absorbs the light in infrared-visible light ranges and converts some of the light into heat. The light-to-heat conversion layer 202 should have an optical density and includes a light absorbing material. Examples of the light-to-heat conversion layer 202 may include a metal layer containing aluminum oxide or aluminum sulfide as the light absorbing material, and a polymeric organic layer containing carbon black, graphite or an infrared dye as the light absorbing material. Here, the organic layer is preferably formed to a thickness ranging from 100 to 5,000 Å (Angstrom) using vacuum deposition, electron beam deposition or sputtering. The organic layer is preferably formed to a thickness ranging from 0.1 to 10 μm using a general film coating method, such as roll coating, gravure coating, extrusion coating, spin coating, or knife coating.

Although not shown, the doner substrate 200 may include a first intermediate layer and a first buffer layer.

The first intermediate layer may be positioned between the light-to-heat conversion layer 202 and the transfer layer 203. The first intermediate layer may prevent the light absorbing material contained in the light-to-heat conversion layer 202, e.g., carbon black, from contaminating the transfer layer 203 formed in a subsequent process. The first intermediate layer may be made of an acrylic resin or an alkyd resin. The forming of the first intermediate layer may be performed through a general coating step, such as solvent coating, and an ultraviolet (UV) curing step.

When the first buffer layer is formed between the light-to-heat conversion layer 202 and the transfer layer 203 or when the first intermediate layer is provided, the first buffer layer may be positioned between the first intermediate layer and the transfer layer 203. The first buffer layer may prevent an organic layer formed on the transfer layer 203 from being damaged. When the first buffer layer is formed between the light-to-heat conversion layer 202 and the transfer layer 203 or when the first intermediate layer is provided, the first buffer layer may effectively adjust adhesion between the first intermediate layer and the transfer layer 203. The first buffer layer may include at least one of an insulating material, a metal and a metal oxide.

The transfer layer 203 may be positioned on the light-to-heat conversion layer 202. The transfer layer 203 may include substantially the same material as the organic layers 21, 22 and 23 and may have substantially the same stacked structure as the organic layers 21, 22 and 23.

The doner substrate 200 may be positioned on the substrate 10 to allow the transfer layer 203 to face the first electrode 41 of the substrate 10.

Referring to FIG. 13, after the doner substrate 200 is positioned on the substrate 10, laser may be irradiated toward the doner substrate 200. In detail, the laser may be irradiated into regions of the doner substrate 200, the regions corresponding to the edge portions of the organic layers 21, 22 and 23 and positioned vertically above the pixel defining film 40 adjacent to the edge portions, which is, however, provided only for illustration, but the present disclosure does not limit the laser irradiation positions to those illustrated herein. That is to say, the laser irradiation positions may vary according to the position of the cover film 30 disposed.

Referring to FIG. 14, the cover film 30 may be formed on the edge portions of the organic layers 21, 22 and 23 and the pixel defining film 40 by laser irradiation. FIG. 14 illustrates that the cover film 30 is formed on the edge portions of the organic layers 21, 22 and 23 and the pixel defining film 40 adjacent thereto. However, the present disclosure does not limit the forming position of the cover film 30 to those illustrated herein. As described above with regard to the organic light emitting display devices according to some embodiments of the present disclosure, the cover film 30 may extend toward a central portion of each of the organic layers 21, 22 and 23 or the pixel defining film 40 adjacent thereto.

In the method for manufacturing the organic light emitting display device according to the embodiment of the present disclosure, an LITI based transfer method is used in forming the cover film 30, but the present disclosure does not limit the step of forming the cover film 30 to that illustrated herein. That is to say, in the method for manufacturing the organic light emitting display device according to the embodiment of the present disclosure, the transfer method for forming the cover film 30 may include radiation induced sublimation transfer (RIST) method, and a laser induced pattern-wise sublimation (LIPS) method, in addition to the LITI based transfer method.

Hereinafter, a method for manufacturing an organic light emitting display device according to another embodiment of the present disclosure will be described.

The method for manufacturing the organic light emitting display device according to the embodiment of the present disclosure is different from the method for manufacturing the organic light emitting display device according to the previous embodiment shown in FIGS. 10 to 14 in that disposing of a cover film 30 at least partially overlapping edge portions of the organic layers 21, 22 and 23 includes printing a pattern on the organic layers 21, 22 and 23.

In the method for manufacturing the organic light emitting display device according to the embodiment of the present disclosure, the forming of the cover film 30 may be performed in various printing methods. Non-limiting examples of the printing methods may include an inkjet printing method, a nozzle printing method, a Toppan printing method, and so on. However, the present disclosure does not limit the printing method to those listed herein.

In the method for manufacturing the organic light emitting display device according to the embodiment of the present disclosure, the disposing of the cover film 30 at least partially overlapping the edge portions of the organic layers 21, 22 and 23 may include forming the cover film 30 using deposition.

Non-limiting examples of the deposition may include vacuum deposition, electron beam deposition and sputtering. In addition, a fine metal mask (FMM) may be used in the forming of the cover film 30. Further, the cover film 30 may be formed by small mask scanning (SMS).

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. An organic light emitting display device, comprising:
a substrate;
a first electrode positioned on the substrate;
a pixel defining film positioned on the substrate and at least partially exposing the first electrode;
an organic layer positioned on the first electrode and having a central portion and an edge portion; and
a cover film at least partially overlapping the edge portion of the organic layer.

2. The organic light emitting display device of claim 1, wherein at least a portion of the cover film overlaps the pixel defining film adjacent thereto extending toward the pixel defining film.

3. The organic light emitting display device of claim 1, wherein the central portion includes a light emitting area.

4. The organic light emitting display device of claim 1, wherein the central portion and the edge portion of the organic layer have non-uniform thicknesses.

5. The organic light emitting display device of claim 1, further comprising a second electrode disposed on the organic layer.

6. The organic light emitting display device of claim 1, wherein the cover film is made of a non-conductive material.

7. The organic light emitting display device of claim 1, wherein the cover film has a thickness in a range of 10 Å (angstrom) to 5 μm.

8. The organic light emitting display device of claim 1, wherein the cover film includes at least one of silicon oxide and silicon nitride.

9. An organic light emitting display device, comprising:
a substrate;
a first electrode positioned on the substrate;
a plurality of pixels exposing at least a portion of the first electrode;
an organic layer positioned on each of the plurality of pixels; and
a cover film disposed along edges of the pixels.

10. The organic light emitting display device of claim 9, wherein the organic layer includes a central portion and an edge portion, and the cover film covers the edge portion.

11. The organic light emitting display device of claim 9, wherein the central portion includes a light emitting area.

12. The organic light emitting display device of claim 9, further comprising a second electrode disposed on the organic layer.

13. The organic light emitting display device of claim 9, wherein the plurality of pixels are arranged in a matrix configuration, and the cover film is disposed along edges of the plurality of pixels.

14. The organic light emitting display device of claim 9, wherein the cover film is made of a non-conductive material.

15. The organic light emitting display device of claim 9, wherein the cover film has a thickness in a range of 10 Å (angstrom) to 5 μm.

16. The organic light emitting display device of claim 9, wherein the cover film includes at least one of silicon oxide and silicon nitride.

17. A method for manufacturing the organic light emitting display device, the method comprising:
preparing a substrate, the substrate including a first electrode positioned on the substrate, and a pixel defining film positioned on the substrate and at least partially exposing the first electrode;
patterning an organic layer having a central portion and an edge portion on the first electrode; and
disposing a cover film at least partially overlapping the edge portion of the organic layer.

18. The method of claim 17, wherein the disposing of the cover film at least partially overlapping the edge portion of the organic layer comprises:
positioning a doner substrate on the substrate to face the first electrode of the substrate, the doner substrate including a base layer, a light-to-heat conversion layer positioned on the base layer and a transfer layer positioned on the light-to-heat conversion layer; and
transferring the transfer layer onto the pixel defining film of the substrate by irradiating laser on the doner substrate.

19. The method of claim 17, wherein the disposing of the cover film at least partially overlapping the edge portion of the organic layer comprises printing the cover film pattern on the organic layer,

20. The method of claim 19, wherein the printing of the cover film pattern on the pixel defining film comprises patterning the cover film pattern using one selected from the group consisting of an inkjet printing method, a nozzle printing method, and a Toppan printing method.
